(19) United States
(12) Patent Application Publication
(10) Pub. No.: US 2018/0204972 A1
(43) Pub. Date: Jul. 19, 2018

(54) NO GRAIN BOUNDARY CRYSTAL Cu2S THIN FILMS FOR SOLAR ENERGY CONVERSION

(71) Applicant: UCHICAGO ARGONNE, LLC, Chicago, IL (US)

(72) Inventors: Alex B. Martinson, Naperville, IL (US); Shannon Riha, Stevens Point, WI (US)

(73) Assignee: UCHICAGO ARGONNE, LLC, Chicago, IL (US)

(21) Appl. No.: 15/862,561

(22) Filed: Jan. 4, 2018

Related U.S. Application Data
(60) Provisional application No. 62/447,794, filed on Jan. 18, 2017.

(51) Int. Cl. H01L 31/18; H01L 31/0445; H01L 31/0296

(52) U.S. Cl. CPC H01L 31/1836; H01L 31/1828; H01L 31/0296; H01L 31/0445

(57) ABSTRACT

The present invention comprises thin film Cu₂S with ultra-large grains or in the best case no grain boundaries (a single crystal thin film). Based on our recent successes in atomic layer epitaxy of other materials we sought and found a suitable substrate (namely GaAs) that induces what appear to be Cu₂S single crystal thin films.

### CROSS-REFERENCE TO RELATED APPLICATIONS

This application claims the benefit of and priority to U.S. Provisional Patent Application No. 62/447,794, filed on Jan. 18, 2017, the contents of which are incorporated by reference herein in their entirety.

The United States Government claims certain rights in this invention pursuant to Contract No. W-31-109-ENG-38 between the United States Government and the University of Chicago and/or pursuant to DE-AC02-06CH11357 between the United States Government and UChicago Argonne, LLC representing Argonne National Laboratory.

### TECHNICAL FIELD

The present disclosure relates generally to methods, systems, and compositions of matter relating to crystal Cu₂S Thin Films, more specifically such thin films with little to no grain boundary.

### BACKGROUND

Photovoltaic (PV) devices have been the focus of research for decades. However, various barriers have proven difficult to overcome in making PV devices competitive with alternatives, such as those powered by fossil fuels. In particular, there still remains a need to identify and design efficient, environmentally benign, and cost-effective PV for the large-scale deployment of solar energy. Current thin film technologies based on CdTe or CuInGaSe₂ materials have met the efficiency demand and are being fabricated on the industrial scale. However, toxicity concerns with Cd, coupled with the low natural abundance of Te and In, make these technologies neither environmentally benign nor scalable to large product models, both of which contribute to a poor cost effectiveness in the long term.

Photovoltaic devices based on Cu₂S, on the other hand, have the potential to meet all three requirements: efficient, environmentally benign, and low cost. Thus, devices based on a CdS/Cu₂S heterostructure have been studied for many years. Through a simple solution-based topotaxial exchange, Cu₂S thin films could be grown directly on CdS with minimal effort, resulting in pilot-scale device efficiencies of 10%. To put this efficiency breakthrough into perspective, PV based on silicon were only around 11% but cost significantly more to produce. However, this construct exhibited a significant flaw, the Cu₂S/CdS heterojunction is unstable.

Since then, the scientific community has been making minimal strides to revolutionize Cu₂S-based PV. Numerous groups have published on the solution-based synthesis of Cu₂S nanocrystals, which can be deposited into a thin film via drop casting, spin coating, or doctor-blading. In addition, work has been done to investigate the degradation mechanism of Cu₂S to better understand its stability faults as well as proposed a mechanism to stabilize the devices. Attempts have also been made to pair Cu₂S with an n-type oxide material to minimize Cu diffusion across the heterojunction and alleviate the use of Cd-based materials. To date, however, Cu₂S PV devices made via methods other than the direct topotaxial exchange on CdS have not achieved the seminal 10% efficiency reported in the early 1980s. Thus, there remains a need for a PV device material that exhibits above 10% efficiency but also utilizes Cu₂S.

### SUMMARY

Embodiments described herein relate generally to thin film Cu₂S.

One embodiment relates to methods for forming thin films with ultra-large grains or no grain boundaries. The thin films are formed through epitaxial growth on a lattice matched substrate.

Another embodiment relates to articles of manufacture comprising thin film Cu₂S. The thin films exhibit PV efficiencies greater than 10% and have no grain boundary.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are therefore, not to be considered limiting of its scope, the disclosure will be described with additional specificity and detail through use of the accompanying drawings.

FIG. 1A shows a side profile SEM image of Cu₂S thin film on a GaAs(111) substrate; FIG. 1B shows a top down profile SEM image of Cu₂S thin film on a GaAs(111) substrate; FIG. 1C shows a side profile SEM image of Cu₂S thin film on a Si substrate, FIG. 1D shows a top down profile SEM image of Cu₂S thin film on a a Si substrate. The lack of discrete grains in FIGS. 1A and 1B suggests epitaxial growth. FIGS. 1E-G show XRD data of the Cu₂S thin film grown on GaAs(111) substrate: FIG. 1E further supports epitaxial growth, while the rocking curve FIG. 1F of the Cu₂S(004) plane indicates a tight distribution of crystal mosaic. FIG. 1G shows a 30° shift between the GaAs and Cu₂S peaks in the phi-scan highlights the epitaxial relationship between Cu₂S[0001] ∥ GaAs[111] and Cu₂S[1-100] ∥ GaAs[1-10], where ∥ denotes parallel lattice directions. FIG. 1H is a time-resolved photoluminescence data shows the dramatic enhancement in photoexcited carrier lifetime with increased grain size.

FIG. 2 shows a rocking curve of the Cu₂S(103) reflection highlights the quality of the Cu₂S thin films in-plane.

FIG. 3A shows steady state photoluminescence of the bare GaAs(111) substrate (red line) and the Cu₂S thin film grown on GaAs(111) substrate (black line). FIG. 3B shows additional time-resolved photoluminescence data revealing significantly longer excited state lifetime of epi-Cu₂S/GaAs(111) relative to the non-epitaxial counterpart.

FIG. 4 is a transmission electron microscope image of the substrate-film interface demonstrating epxitaxy.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION OF VARIOUS EMBODIMENTS

It has been discovered that there is a correlation between the minority carrier lifetime and grain boundaries. Specifically, photoexcited charge carrier lifetimes increased with increasing film thickness as well as increasing lateral grain area, indicating that interface states and surface traps act as dominant recombination centers. Similar recombination mechanisms have also been observed in CIGS and CdTe PV devices, suggesting that enhancing grain growth may also be the key to obtaining high device efficiencies in Cu₂S-based thin film solar cells.

Epitaxial growth is one method that affords the opportunity to improve upon properties and crystalline quality through low defect interfaces, more uniform nucleation, and larger grain size. Traditionally speaking, however, epitaxial growth requires high deposition temperatures and ultrahigh vacuum, limiting its application to a niche market. Atomic layer deposition (ALD), on the other hand, is a vapor-phase, thin film deposition method based on alternating self-limiting surface reactions. The nature of ALD lends itself to be a unique deposition method capable of precise control over thin film thickness and stoichiometry, as well as the ability to deposit conformal coatings over high surface area morphologies. While not typically touted for epitaxial growth, there have been a growing number of reports on epitaxial ALD when using a suitable substrate. Epitaxial growth by ALD offers many advantages over traditional methods—low temperature processing (<300° C.) without the requirement of ultrahigh vacuum—making it suitable for large-area scale up. Here we demonstrate a novel, low temperature epitaxial growth method for Cu₂S thin films as a proof-of-principle that clean interfaces and large grains are the key to enhanced minority carrier lifetimes and efficient Cu₂S PV.

Embodiments described herein relate generally to Cu₂S thin films, more specifically to a material with substantially no grain boundaries, that is single crystal or with all grains oriented. As used herein, “thin film” means less than a continuous film to 5 microns thick. In one embodiment, one or more intervening layers may be included between the substrate and the Cu₂S thin film, such as to enhance bonding or to serve as a step between lattice constraints of the substrate and thin film. Further, such intervening layer or layers may also be sacrificial, such as one to be etched to release the epi-Cu2S and allow re-use of the substrate (such as a GaAs template).

The Cu₂S thin film is grown on a lattice matched substrate. Cu₂S has a lattice constant: 3.961 Å. The substrate may have a lattice constant with a <5% to 10% mismatch of the thin film, preferably less than 5%, more preferably less than 1. In one embodiment, the Cu₂S thin film is grown on a substrate having a wurtzite (hexagonal) cut. For example, one embodiment use as a substrate GaA (GaAs(111): lattice constant of 3.997 Å (<1%)). In particular embodiments, the GaA has a <111>crystallographic cut. Alternative substrates include CdS, MnS, ZnS, InN.

The growth may be by Atomic Layer Deposition (“ALD”). Alternative embodiments may use Chemical Vapor Deposition, sputtering, or similar deposition techniques. In one embodiment, the ALD is low temperature ALD (below 225° C., below 200° C., such as at 165° C., 170° C., 180° C., and 190° C. and preferably about 165° C.). In one embodiment, standard ALD conditions are used. ALD conditions may include: saturating exposure times (2.0 s for Cu and 0.1 s for H₂S), Cu precursor is an amidinate, heated to 165° C. H₂S is used as the S source and delivered at room temperature.

The methods described herein produce Cu₂S thin film that is a single crystal thin film having effectively no grain boundaries. No effective grain boundaries means, for example, the Cu₂S thin film may be a single crystal or, alternatively, the Cu₂S film may have grains but with all grains oriented and without high angle grain boundaries.

In one embodiment, the article of manufacture with the Cu₂S thin film described herein has a photovoltaic efficiency of at least 10%. As used herein, photovoltaic efficiency means the maximum power output divided by the incident radiation flux times the area of the collector:

Max Eff.=(max power output)/((incid. rad. Flux)×(Collector Area))

Experiments were preformed to test embodiments for Cu₂S thin film. Examples of such experiments are described below for illustrative purposes.

### Experimental Methods

Materials: Bis(N,N′-disec-butylacetamidinato)dicopper(I) precursor (CuAMD) was purchased from DOW Chemical Company and 3.8% H₂S was purchased from AirGas. Double-side, undoped, single-crystal GaAs(111) substrates were purchased from MTI Corporation and stored in an inert glove box until use.

Deposition: Prior to Cu₂S deposition, silicon and quartz substrates were cleaned by a successive sonication in acetone and isopropanol for 10 minutes each. Following the isopropanol sonication, the substrates were rinsed with isopropanol and blown dry with a stream of N₂. GaAs(111) single-crystal substrates were used as-received with no pre-cleaning steps. Alternatively, a pre-cleaning step may be used to ensure the surface is chemically clean. The substrates were allowed to equilibrate at the deposition temperature.

Cu₂S thin films were deposited in an Ultratech-Cambridge Nanotech Savannah 200 ALD coupled to an N₂ filled glove box following a previously established procedure (ACS Appl. Mater. Interfaces, 2013, 5 (20), pp 10302-10309, incorporated herein by reference). Briefly, films were deposited by alternating exposures of CuAMD and H₂S precursors at deposition temperatures of 165-190° C. First, CuAMD, heated to 150° C., was introduced into the ALD reaction chamber using a 2.0 s dose. Subsequently, the H₂S, held at room temperature, was introduced into the reaction chamber using a 0.1 s pulse. The CuAMD and H₂S precursors were separated in time using a 15.0 s (deposition temperature≤170° C.) or 12.0 s (deposition temperature>170° C.) purge with N₂. With a growth rate of ˜0.5 Å/cycle, 2000 ALD cycles were used to achieve a 100 nm film.

Characterization X-ray diffraction (XRD) was collected on a Philips X'Pert Pro MRD diffractometer using Cu Kα (λ=1.5418 Å) operating at 30 kV/30 mA. For rocking-curve measurements and general diffraction, incident X-rays were conditioned and collimated using a 60 mm graded parabolic W/Si mirror with a 0.8° acceptance angle and a ⅛° vertical beam divergence slit, respectively. A 0.27° parallel plate collimator, a detector slit, and a flat pyrolytic graphite monochromator were positioned in front of the PW3011/20 sealed proportional point detector to collect the scattered beam. To confirm epitaxial relationship between the Cu₂S film and GaAs substrate, we utilized a 1° incident beam divergence slit and removed the detector slit and parallel plate collimator. This approach increased reciprocal space sampling volume and improved count rate while reducing resolution, thereby enabling quick confirmation of Cu₂S/Ga(111) epitaxy.

Scanning electron microscopy images were collect on a Hitachi S4700 SEM equipped with an energy dispersive x-ray analysis detector.

Time-resolved photoluminescence (TRPL) spectroscopy was collected using 35 fs excitation pulses at 400 nm focused to a 400 micron diameter spot. Emitted photons were collected with a lens and directed to a 150 mm spectrograph and streak camera detector that operated in a photon counting mode.

### Results

Finding a suitable epitaxial template (ideally single crystalline) for epitaxial ALD of würtzite Cu₂S requires a substrate that is well lattice matched, provides a clean and chemically compatible surface for epitaxy, and does not undergo labile cation exchange with copper. For the experiments described above, GaAs(111) was selected as an epitaxial template for Cu₂S deposition given: (1) its ability to project a hexagonal lattice constant of a=3.998 Å (<1% lattice mismatch to wUrtzite Cu₂S), (2) there exists no evidence of labile cation exchange, and (3) the commercial availability of 4 inch diameter “epi-ready” wafers.

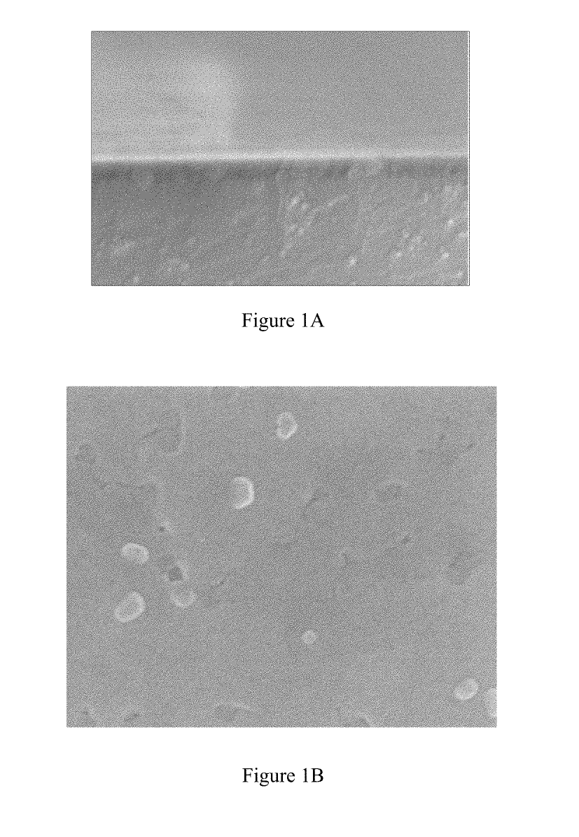

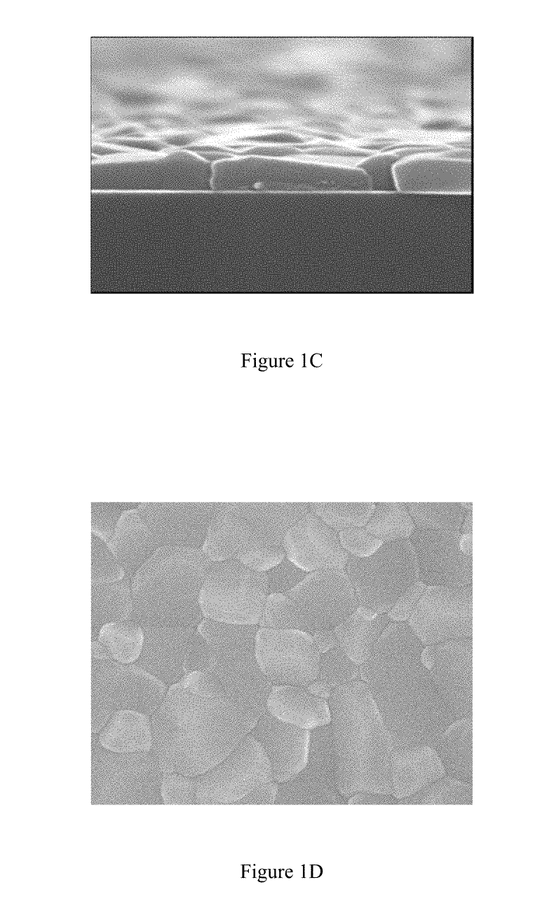

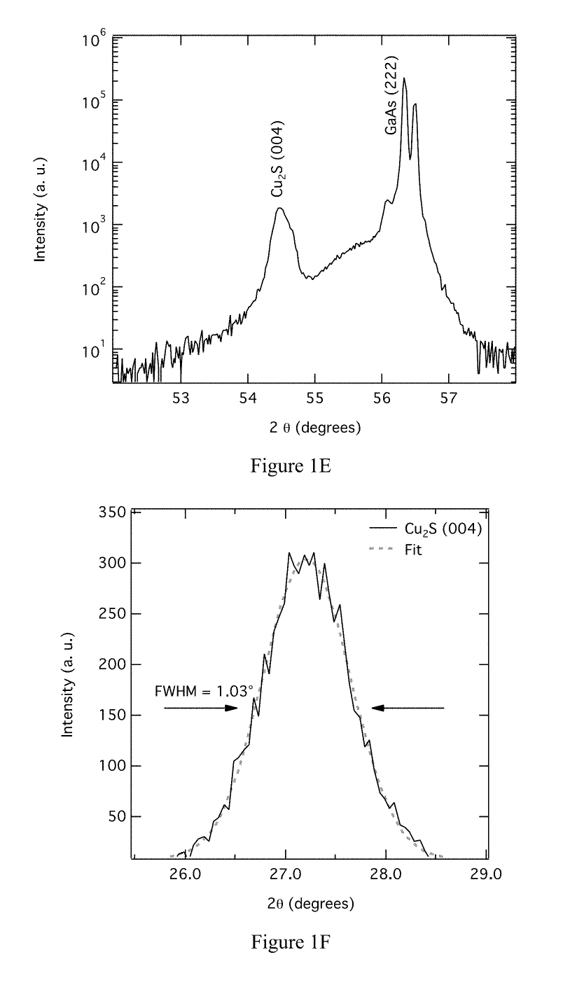

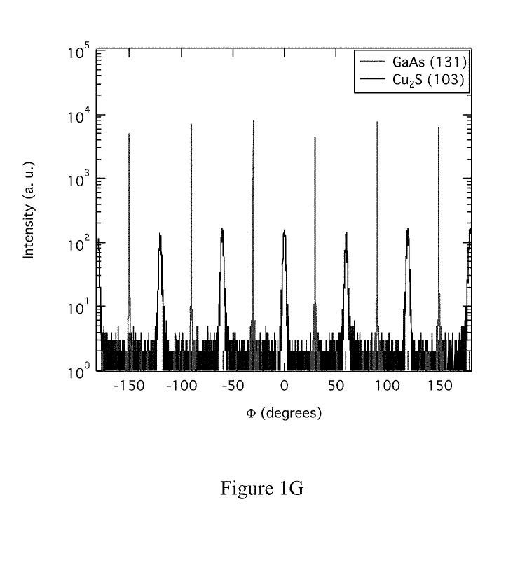

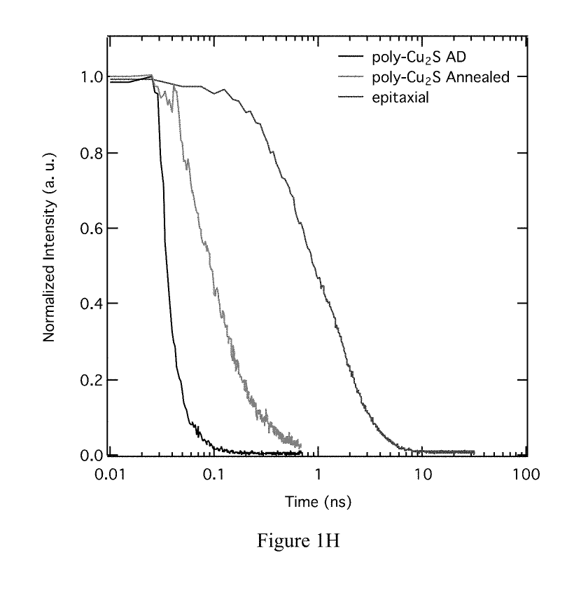

Cu₂S thin films were grown by ALD at 165, 170, 180, and 190° C. on GaAs(111) as well as on silicon substrates for comparison and analysis. FIGS. 1A-1D displays SEM images taken of films grown on Si (panels a, c, e, and g) and GaAs(111) (panels b, d, f, and h) at the different growth temperatures. At low deposition temperatures (165 and 170° C.) SEM analysis of Cu₂S films prepared on Si and GaAs(111) substrates highlights an appalling difference in film morphology. When grown on Si (FIGS. 1a and c), discrete grain boundaries are apparent in both the top and side profiles, resembling a crystal mosaic, with an average grain size on the order of a couple hundred nanometers. On the contrary, when grown on GaAs(111), the Cu₂S surface morphology appears smooth without the presence of distinct grains, FIGS. 1b and d. l The phase contrast between the Cu₂S and the GaAs in the side profile images (insets) was the only indication that Cu₂S thin films were indeed present on the GaAs(111) substrates. As the growth temperature increased, the apparent grain size of the Cu₂S thin film on silicon and GaAs(111) decreased, and the surface appeared to become more textured as indicated by the larger spacing between grains. The surface morphology of the Cu₂S thin film on GaAs(111) changed most significantly at higher deposition temperatures compared to what was observed at deposition temperatures of 165 and 170° C. Discrete grains were discernable, with grain sizes of 50-200 nm in diameter, closer resembling Cu₂S films grown on silicon. It is clear that in order to obtain Cu₂S thin films with large grain sizes, growth at temperatures of 170° C. and lower is necessary, regardless of substrate.

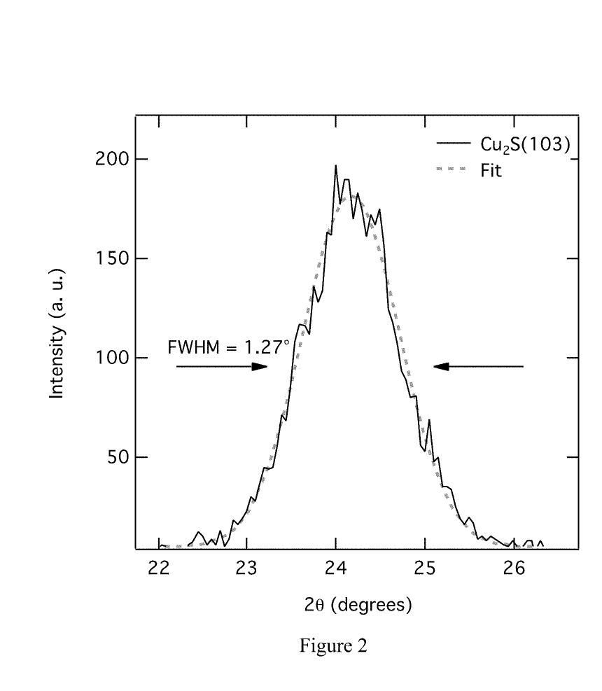

To go beyond the surface morphology and better understand the difference in the crystalline structure of the Cu₂S thin films grown on the two different substrates, we turned to XRD. FIG. 2 shows XRD data of a 100 nm Cu₂S thin film deposited on GaAs(111) at 165° C. Specular thin film diffraction data near the second allowed GaAs reflection (222) is plotted in FIG. 2a. The (004) peak of Cu₂S observed at lower 2θ indicates that the Cu₂S thin film has slightly larger d-spacing as expected. Diffraction from other families of Cu₂S crystallographic planes was not observed, indicating the ALD Cu₂S thin films were c-plane oriented. The fact that the anion sublattices for GaAs and Cu₂S along the (111) and (002) directions, respectively, are well matched facilitates this preferred orientation. From previous analysis, Cu₂S thin films deposited by non-epitaxial ALD were also c-plane oriented which may further be beneficial in the epitaxial growth of Cu₂S on GaAs(111). To determine the degree of preferential orientation, a rocking-curve measurement was performed on the Cu₂S(004) plane and the data plotted in FIG. 2b. A full-width-at-half-maximum (FWHM) value of 1.03° was determined indicating strong (00/) out-of-plane orientation and a tight distribution of crystal mosaic. To gain insight into the epitaxial relationship between the Cu₂S film and the GaAs(111) substrate, we investigated the relative azimuthal (φ) positions of the GaAs{1̅31} and Cu₂S{103} families of reflections. FIG. 2c shows a expected 6-fold symmetry for both sets of reflections with a 30° shift between the GaAs and Cu₂S peaks, demonstrating a epitaxial relationship of Cu₂S[113]∥ GaAs[1̅31] and Cu₂S[001]∥ GaAs[222], where ∥ denotes parallel lattice directions. Finally, a rocking curve measurement of the Cu₂S(103) reflection, FIG. 2, gives a FWHM of 1.27° demonstrating the quality of the Cu₂S in-plane.

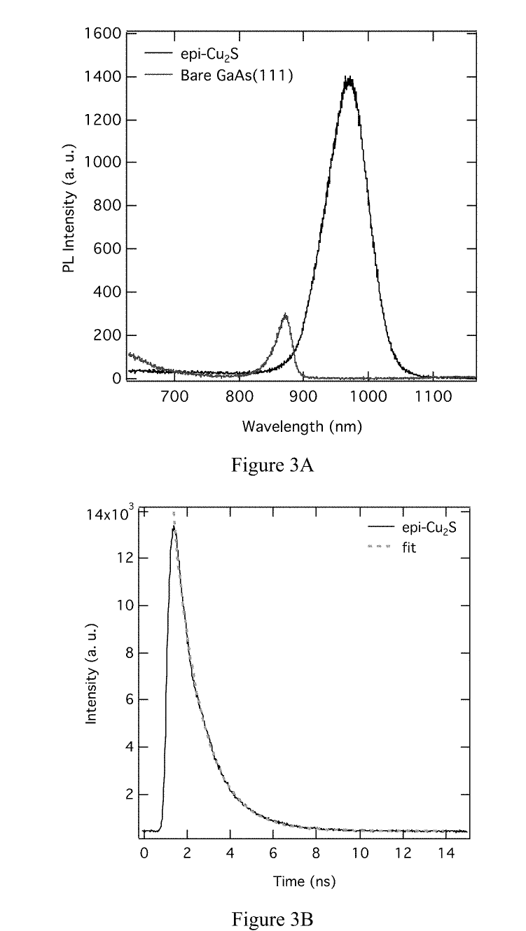

High-resolution TEM imaging was used to further analyze the interface between the Cu₂S thin film and the GaAs(111) substrate. FIG. 3 corroborate the XRD data showing significantly longer excited state lifetime of epi-Cu₂S/GaAs(111) relative to the non-epitaxial counterpart.

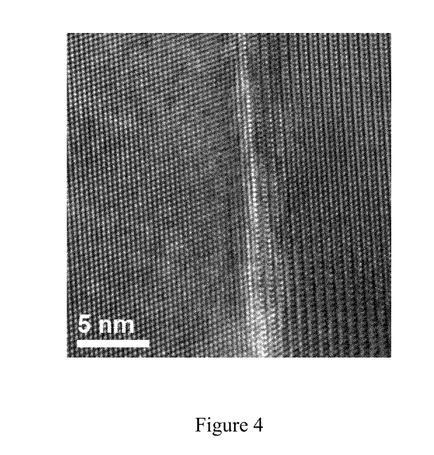

In a previous report, a correlation between the grain size of Cu₂S thin films and the photoexcited carrier lifetimes was observed. Specifically, it was found that as the grain size increased, so did the lifetime, with the highest reported photoexcited carrier lifetime of ˜30 ps for a lateral grain area of 0.12 μm². The decay mechanism of the photoexcited carrier proceeds via relaxation into trap states—with energy levels just below the conduction band edge—as evidence from a long-lived photoinduced absorption in the transient absorption spectra. Therefore we speculate that increasing the grain size is a key step in achieving device efficiencies exceeding 10%. To validate this hypothesis, time-resolved streak camera photoluminescence measurements (TRPL) were performed with an excitation wavelength of 405 nm. FIG. 4 displays the photoluminescence data for ALD Cu₂S on GaAs(111). A snapshot of the PL signal after 1 ps is plotted in FIG. 4a. A strong, symmetric PL peak is observed at 967 nm with a FWHM of 78.6 nm The absence of the GaAs PL peak in the epi-Cu₂S film on GaAs(111) suggests that the photoexcited charge carriers are transferred to the Cu₂S film or quenched by trap states at the interface.

The minority carrier lifetime is determined by fitting the TRPL data plotted in FIG. 4b for the epi-Cu₂S thin film on GaAs(111) at 970 nm. The data follows a single exponential decay with a calculated τ=1.307±0.003 ns. Compared with our previous report this is nearly a 50× increase in the minority carrier lifetime measured for ALD Cu₂S thin films. Extrapolating the fit for lifetime-vs-grain area reported (FIG. 4c of reference J. Phys. Chem. Lett., 2014, 5 (22), pp 4055-4061) a crude estimate of the grain sizes in the epi-Cu₂S sample is on the order of 4.1-7.2 μm².

### Conclusions

Decades ago, Cu₂S showed great promise for cost-effective and efficient thin film PV with CdS/Cu₂S heterojunction device efficiencies reaching 10%; however, rapid degradation of early devices rendered this technology to be abandoned. Recent attempts at reviving Cu₂S-based PV have fallen short of the record efficiency presumably due to short minority lifetimes in Cu₂S thin films as a result of photoexcited carrier relaxation at grain boundaries. The results presented here demonstrate a way to alleviate that hurdle. For the first time, Cu₂S thin films have been grown epitaxially using a Cd-free template by a low temperature (<200° C.) ALD approach. Discrete grain boundaries are diminished in the epitaxial Cu₂S thin films suggesting an increase in the grain size compared to non-epitaxial ALD Cu₂S films grown on Si substrates. More importantly, the epitaxial Cu₂S thin films show a remarkable enhancement in the minority carrier lifetime, increasing from 10 s of ps to ns. Specifically, 100 nm thick epitaxial Cu₂S thin films on GaAs(111) have minority carrier lifetimes of 1.3 ns. Coupling this minority carrier lifetime with the carrier diffusivity, we calculated the F_{PV} for Cu₂S thin films grown by epitaxial ALD. Based on these results, we estimate with that PV devices made with epitaxial Cu₂S and free of CdS are indeed capable of producing power conversion efficiencies around 10-15%.

As used herein, the singular forms “a”, “an” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. An article of manufacture comprising:
a substrate having a
a thin film of Cu₂S deposited on the substrate;
wherein the Cu₂S thin film has no effective grain boundaries.

2. The article of manufacture of claim 1, wherein the substrate presents a hexagonal lattice with constant between 3.6 and 4.4 Angstroms.

3. The article of manufacture of claim 1, wherein the article of manufacture has a photovoltaic efficiency of greater than 10%.

4. The article of manufacture of claim 1, wherein the thin film is deposited on a <111> surface of the substrate.

5. The article of manufacture of claim 1, wherein the substrate is GaA.

6. The article of manufacture of claim 1, wherein the thin film is a single crystal.

7. The article of manufacture of claim 1, further comprising an intervening layer between the substrate and the thin film.

8. The article of manufacture of claim 1, wherein the substrate and the thin film have a lattice mismatch of less than 10%.

9. A method of manufacture comprising:
providing a substrate;
epitaxially depositing a thin film of Cu₂S;
wherein the substrate and the thin film are latticed matched to within 10%.

10. The method of manufacture of claim 9, wherein the substrate is GaA.

11. The method of manufacture of claim 9, wherein the epitaxial ALD is at below below 225° C.

12. The method of manufacture of claim 9, wherein the epitaxial ALD is at below below 200° C.

13. The method of manufacture of claim 9, wherein the thin film has a thickness of between 0.1 and 5000 nm.

14. The method of manufacture of claim 9, further comprising, prior to epitaxially depositing the thin film, depositing an intervening layer on the substrate, wherein the thin film is epitaxially deposited on the intervening layer.

15. The method of manufacture of claim 14, further comprising removing the interviewing layer, releasing the thin film from the substrate.

16. The method of claim 9, wherein the epitaxial deposition is by atomic layer deposition.

17. The method of claim 16, wherein epitaxial deposition by atomic layer deposition comprises alternating exposures of CuAMD precursor and H₂S precursor.

18. The method of claim 16, wherein the CuAMd precursor is dosed for 2 seconds.

19. The method of claim 16, wherein the H₂S precursor is dosed for 0.1 s.
